(19) United States
(12) Patent Application Publication
(10) Pub. No.: US 2009/0283039 A1
(43) Pub. Date: Nov. 19, 2009

(54) ROBUST OUTLET PLUMBING FOR HIGH POWER FLOW REMOTE PLASMA SOURCE

(75) Inventors: JOHN M. WHITE, Hayward, CA (US); Soo Young Choi, Fremont, CA (US); Beom Soo Park, San Jose, CA (US); Gaku Furuta, Sunnyvale, CA (US); Young Jin Choi, Santa Clara, CA (US); Robin L. Tiner, Santa Cruz, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/467,477

(22) Filed: May 18, 2009

Related U.S. Application Data
(60) Provisional application No. 61/054,431, filed on May 19, 2008.

(51) Int. Cl. C23C 16/54; F28D 7/00

(52) U.S. Cl. 118/723 R; 165/164

(57) ABSTRACT

The present invention generally includes a coupling between components. When igniting a plasma remote from a processing chamber, the reactive gas ions may travel to the processing chamber through numerous components. The reactive gas ions may be quite hot and cause the various components to become very hot and thus, the seals between apparatus components may fail. Therefore, it may be beneficial to cool any metallic components through which the reactive gas ions may travel. However, at the interface between the cooled metallic component and a ceramic component, the ceramic component may experience a temperature gradient sufficient to crack the ceramic material due to the heat of the reactive gas ions and the coolness of the metallic component. Therefore, extending a flange of the metallic component into the ceramic component may lessen the temperature gradient at the interface and reduce cracking of the ceramic component.

### CROSS-REFERENCE TO RELATED APPLICATIONS

This application claims benefit of U.S. Provisional Patent Application Ser. No. 61/054,431 (APPM/013173L), filed May 19, 2008, which is herein incorporated by reference.

### BACKGROUND OF THE INVENTION

1. Field of the Invention

Embodiments of the present invention generally relate to a coupling between a metal cooling block and a ceramic gas tube.

2. Description of the Related Art

After numerous plasma processes, exposed components within the processing chamber may become coated with material that could flake off and contaminate further processes. In order to reduce contamination, the processing chamber and the exposed processing chamber parts may need to be periodically cleaned. There is a need in the art for an apparatus and method to clean a processing chamber.

### SUMMARY OF THE INVENTION

The present invention generally includes a coupling between components. When igniting a plasma remote from a processing chamber, the reactive gas ions may travel to the processing chamber through numerous components. The reactive gas ions may be quite hot and cause the various components to become very hot and thus, the seals between apparatus components may fail. Therefore, it may be beneficial to cool any metallic components through which the reactive gas ions may travel. However, at the interface between the cooled metallic component and a ceramic component, the ceramic component may experience a temperature gradient sufficient to crack the ceramic material due to the heat of the reactive gas ions and the coolness of the metallic component. Therefore, extending a flange of the metallic component into the ceramic component may lessen the temperature gradient at the interface and reduce cracking of the ceramic component.

In one embodiment, an apparatus includes a remote plasma source, a gas feedthrough tube, and a cooling block. The cooling block may be coupled between the remote plasma source and the gas feedthrough tube. The cooling block may have a flange that extends into the interior of the gas feedthrough tube.

In another embodiment, a cooling block includes a cooling block body having an outside surface and one or more cooling channels within the body, an inlet flange extending from the body at a first elevation, and an outlet flange extending from the body at a second elevation that is different than the first elevation. The body may include a receiving surface that surrounds the outlet flange. The receiving surface may be recessed from the outside surface.

In another embodiment, a gas feedthrough tube includes a gas feedthrough tube body having a first end, a second end, a first inner diameter, and a second inner diameter different than the first diameter.

In another embodiment, a method includes igniting a plasma in a remote plasma source and flowing reactive gas ions from the remote plasma source through a cooling block made of a first material and a gas tube made of a second material different than the first material. The cooling block may extend at least partially into the gas tube. The method may also include flowing a cooling fluid through the cooling block while flowing the reactive gas ions therethrough.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross sectional view of an apparatus 100 according to one embodiment of the invention.

FIG. 2A is a schematic cross sectional view of a gas tube 208 coupled between a cooling block 206 and an end block 202 leading to a processing chamber according to one embodiment of the invention.

FIG. 2B is a schematic cross sectional view of a portion of FIG. 2A.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present invention generally includes a coupling between components. When igniting a plasma remote from a processing chamber, the reactive gas ions may travel to the processing chamber through numerous components. The reactive gas ions may be quite hot and cause the various components to become very hot and thus, the seals between apparatus components may fail. Therefore, it may be beneficial to cool any metallic components through which the reactive gas ions may travel. However, at the interface between the cooled metallic component and a ceramic component, the ceramic component may experience a temperature gradient sufficient to crack the ceramic material due to the heat of the reactive gas ions and the coolness of the metallic component. Therefore, extending a flange of the metallic component into the ceramic component may lessen the temperature gradient at the interface and reduce cracking of the ceramic component.

The invention, as described below, may be practiced in a PECVD system available from AKT, a subsidiary of Applied Materials, Inc., Santa Clara, Calif. It is contemplated that the invention may be practiced in other plasma processing chambers, including those from other manufacturers.

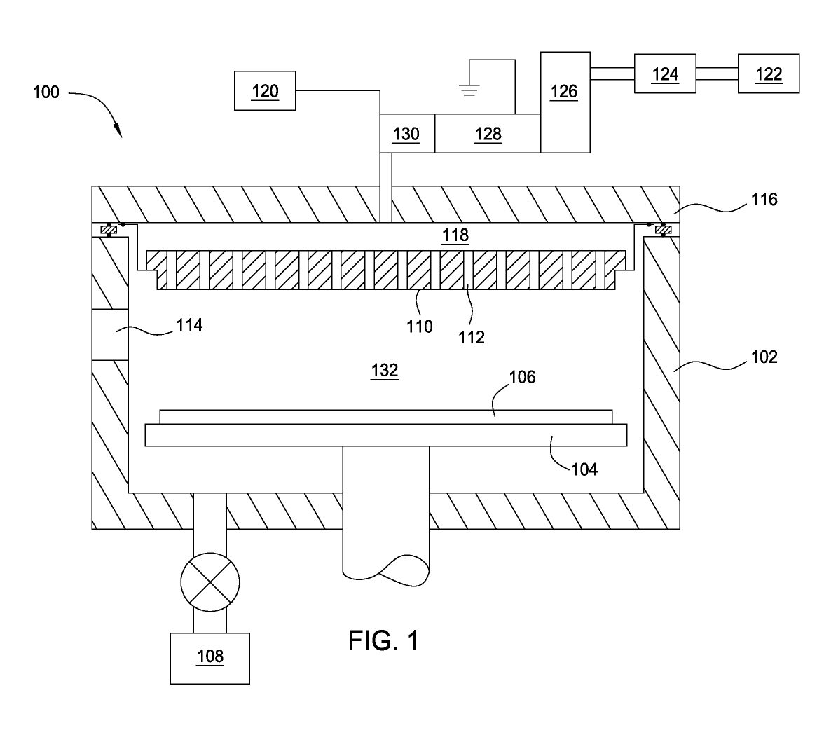

FIG. 1 is a schematic cross sectional view of an apparatus 100 according to one embodiment of the invention. The apparatus 100 comprises a chamber body 102 enclosing a susceptor 104 upon which a substrate 106 may be disposed. The apparatus 100 may be evacuated by a vacuum pump 108 that is coupled with the chamber body 102. The substrate 106 may enter and exit the apparatus 100 through a slit valve opening 114 in the chamber body 102.

Processing gas may be introduced to the apparatus from a processing gas source 122. The gas may travel through a remote plasma source 124, a cooling block 126, a resistor containing a gas tube 128, and an end block 130 before entering the apparatus 100 through the backing plate 116. A power source 120 may be coupled to the end block 130 to provide power to the showerhead 110 that is disposed in the apparatus 100 opposite to the susceptor 104. The processing gas may enter the apparatus 100 through the backing plate 116 into a plenum 118 between the gas distribution showerhead 110 and the backing plate 116. The processing gas may then pass through gas passages 112 in the showerhead 110 into the processing area 132. The resistor may be grounded to ground any current that travels from the power source 120 back in the direction of the gas source 122 and away from the backing plate 116.

The gas tube 128 may comprise an insulating material such as ceramic material to prevent any electrical current from penetrating into the gas tube 128 and igniting processing gas prior to entering the apparatus 100. When cleaning the apparatus, cleaning gas is supplied from the gas source 122 and ignited into a plasma in the remote plasma source 124. The reactive gas ions from the plasma will be sent to the apparatus 100 and be very hot which could lead to failure of any seals between components that are coupled together. Thus, the reactive gas ions may pass through a cooling block 126 before entering the gas tube 128 to cool the reactive gas ions. The cooling block 126 may comprise a metallic material having good heat conductance to permit a cooling fluid to draw heat from the plasma. Therefore, the body of the cooling block 126 may have a lower temperature than the hot, reactive gas ions due to the heat transfer.

The gas tube 128, which may comprise an insulating material, may be coupled to a surface of the cooling block 126. The gas tube 128 will also have the hot, reactive gas ions flowing therethrough. Thus, the gas tube 128 may experience a temperature gradient between the inside of the gas tube 128 through which the hot, reactive gas ions flow and the interface with the cooling block 124. The temperature gradient may lead to cracking of the gas tube 128.

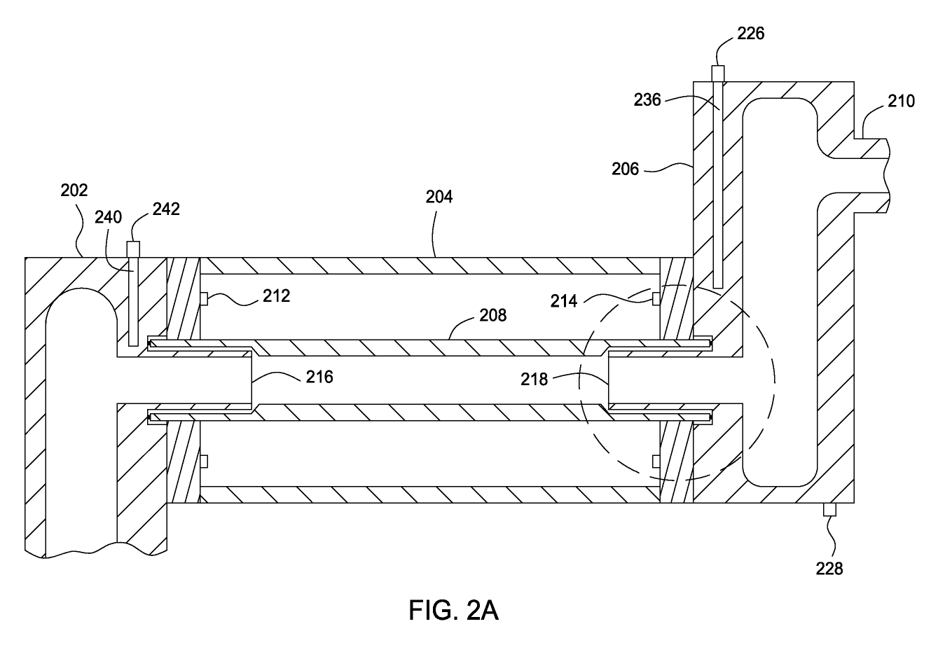

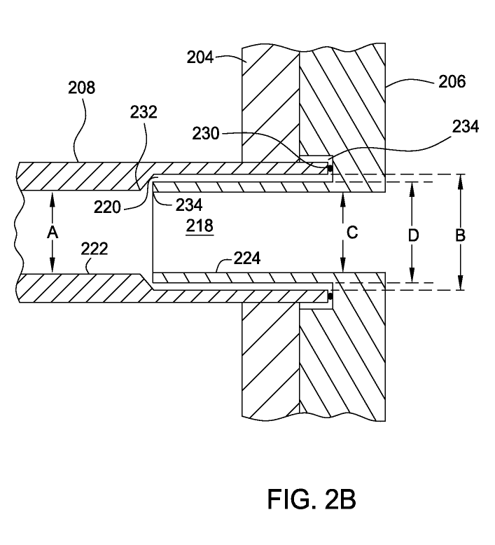

FIG. 2A is a schematic cross sectional view of a gas tube 208 coupled between a cooling block 206 and an end block 202 leading to a processing chamber according to one embodiment of the invention. The gas tube 208 may be disposed in a resistor 204. The resistor 204 may have a metallic wire wrapped around the outside surface of the resistor 204 and coupled to the fastening mechanism 212 that couples the resistor 204 to the end block 202. The wire may permit any electrical current flowing from the power source that is coupled with the end block 202 to flow to ground.

The resistor 204 may comprise an electrically insulating material. In one embodiment, the resistor 204 may comprise ceramic material. The resistor 204 may have the gas tube 208 coupled thereto and extending from one end to another end of the resistor 204. The resistor 204 may be coupled with the end block 202 by one or more fastening mechanisms 212. In one embodiment, the end block 202 may comprise a metallic material. In one embodiment, the end block 202 may comprise aluminum. In coupling the resistor 204 to the end block 202, the gas tube 208 is also coupled to the end block 202 to permit the processing gas and reactive gas ions (from the remote plasma source) to flow through the gas tube 208 and the end block 202 to the processing chamber. The end block 202 may have a flange 216 that extends out from the body of the end block 202 and into the gas tube 208. The end block 202 may have one or more cooling channels 240 therein. Cooling fluid may be introduced to the end block through a cooling fluid inlet 242. In one embodiment, the cooling fluid may comprise air. In another embodiment, the cooling fluid may comprise water. Thus, the walls of the gas tube 208 may enclose the flange 216 of the end block 202 when the gas tube 208 and end block 202 are coupled together.

The resistor 204 may also be coupled to the cooling block 206 using one or more fastening mechanisms 214. In one embodiment, the cooling block 206 may comprise a metallic material. In another embodiment, the cooling block 206 may comprise aluminum. The cooling block 210 may have an inlet flange 210 that couples to the remote plasma source. Cooling fluid may enter the cooling block 206 through a cooling fluid inlet 226, flow in cooling channels 236, and exit the cooling block 206 through a cooling fluid outlet 228. In one embodiment, the cooling fluid may comprise water. In another embodiment, the cooling fluid may comprise air. Similar to the end block 202, the cooling block 206 may have a flange 218 that extends from the body of the cooling block 206 and into the gas tube 208 when the resistor 204 and cooling block 206 are coupled together. When in operation, the reactive gas ions may enter the cooling block 206 through the flange 210, travel through the cooling block 206 and out the flange 218 coupled to the gas tube 208. The reactive gas ions may then travel through the gas tube 208 and the flange 216 of the end block 202. The reactive gas ions then travel through the end block 202 and on to the processing chamber.

FIG. 2B is a schematic cross sectional view of a portion of FIG. 2A. It should be understood that while the coupling between the gas tube 208 and the cooling block 206 is shown, the coupling between the gas tube 208 and the end block 202 is substantially similar. In the embodiment shown in FIG. 2B, the gas tube 208 may extend into a recess 234 formed in the body of the cooling block 206. It is to be noted, however, the recess 234 may not be present and the gas tube 208 may not extend beyond the body of the resistor 204. Thus, in one embodiment, the resistor 204 and gas tube 208 are flush against the outside surface of the cooling block 206 and have the same length.

The inner wall 222 of the gas tube 208 may have a first inside diameter shown by arrow “A” and a second inside diameter shown by arrow “B” that is greater than the first inside diameter. The larger diameter permits the flange 218 of the cooling block 206 to be inserted into the gas tube 208. The flange 218 has an outer diameter shown by arrow “D” and an inside diameter shown by arrow “C”. The outside diameter of the flange 218 may be smaller than the larger inside diameter of the gas tube 208 to permit a gap 220 to be present between the flange 218 and the gas tube 208. The gap 220 may be smaller than the plasma dark space and thus, reduce the likelihood of reactive gas ions that may have ignited into a plasma entering the gap 220. The gap 220 may reduce any particle generation that may occur if the flange 218 and the gas tube 208 rub together. The flange 218 may expand and contract due to the temperature variations between the hot, reactive gas ions for cleaning and the processing gas. Thus, the gap 220 may be sufficiently large to permit the flange 218 to expand without rubbing the gas tube 208, but sufficiently small to reduce plasma formation within the gap 220.

The inside diameter of the flange 218 may be substantially equal to the smallest inside diameter of the gas tube 208 (i.e., “A” may be substantially equal to “C”). By having the diameters substantially equal, the flow of the processing gases may not be disturbed by any abruptions in the gas tube 208 or flange 218.

By extending the flange 218 into the gas tube 208, the gas tube 208 may have a more gradual temperature gradient between the point 230 that abuts the body of the cooling block 206 and the point 232 where the flange 218 ends. The flange 218, by extending out from the body of the cooling block 206, may have a temperature gradient. The end 234 of the flange 218 is furthest away from the body of the cooling block 206 may have a higher temperature when plasma flows through the cooling block 206 as compared to the body of the cooling block 206 because the cooling fluid may not cool the flange 218 to the same extent as the body of the cooling block 206. Thus, the gas tube 208, due to it being adjacent to the flange 218 having a temperature gradient, may have a temperature gradient from the point 230 coupled to the body of the cooling block 206 and the point 232 adjacent to the end 234 of the flange 234. Because of the flange 218, the temperature gradient between the point 230 adjacent the body of the cooling block 206 and the point 232 adjacent the end 234 of the flange 218 may be sufficiently low to reduce the potential for cracking of the gas tube 208.

By extending a flange of a cooling block into the gas tube, plasma may be remotely generated and reactive gas ions delivered to the processing chamber for cleaning the processing chamber.

While the foregoing is directed to embodiments of the present invention, other and further embodiments of the invention may be devised without departing from the basic scope thereof, and the scope thereof is determined by the claims that follow.

1. An apparatus, comprising:
a remote plasma source;
a gas feedthrough tube; and
a cooling block coupled between the remote plasma source and the gas feedthrough tube, the cooling block having a flange that extends into the interior of the gas feedthrough tube.

2. The apparatus of claim 1, wherein the cooling block comprises aluminum.

3. The apparatus of claim 2, wherein the gas feedthrough tube comprises ceramic.

4. The apparatus of claim 3, wherein the gas feedthrough tube has a first inner diameter and a second inner diameter different than the first inner diameter, and wherein the flange has a third inner diameter substantially equal to the first inner diameter.

5. The apparatus of claim 4, wherein the gas feedthrough tube is coupled with an end block at an end opposite to the cooling block, and wherein the end block extends at least partially into the gas feedthrough tube.

6. The apparatus of claim 5, wherein the apparatus is a plasma enhanced chemical vapor deposition apparatus.

7. The apparatus of claim 1, wherein the gas feedthrough tube comprises ceramic.

8. The apparatus of claim 7, wherein the gas feedthrough tube has a first inner diameter and a second inner diameter different than the first inner diameter, and wherein the flange has a third inner diameter substantially equal to the first inner diameter.

9. The apparatus of claim 8, wherein the gas feedthrough tube is coupled with an end block at an end opposite to the cooling block, and wherein the end block extends at least partially into the gas feedthrough tube.

10. The apparatus of claim 9, wherein the apparatus is a plasma enhanced chemical vapor deposition apparatus.

11. The apparatus of claim 1, wherein the gas feedthrough tube has a first inner diameter and a second inner diameter different than the first inner diameter, and wherein the flange has a third inner diameter substantially equal to the first inner diameter.

12. The apparatus of claim 11, wherein the gas feedthrough tube is coupled with an end block at an end opposite to the cooling block, and wherein the end block extends at least partially into the gas feedthrough tube.

13. The apparatus of claim 12, wherein the apparatus is a plasma enhanced chemical vapor deposition apparatus.

14. The apparatus of claim 1, wherein the gas feedthrough tube is coupled with an end block at an end opposite to the cooling block, and wherein the end block extends at least partially into the gas feedthrough tube.

15. The apparatus of claim 14, wherein the apparatus is a plasma enhanced chemical vapor deposition apparatus.

16. The apparatus of claim 1, wherein the apparatus is a plasma enhanced chemical vapor deposition apparatus.

17. A method, comprising:
igniting a plasma in a remote plasma source;
flowing the reactive gas ions from the remote plasma source through a cooling block made of a first material and a gas tube made of a second material different than the first material, wherein the cooling block extends at least partially into the gas tube; and
flowing a cooling fluid through the cooling block while flowing the reactive gas ions therethrough.

18. The method of claim 17, wherein the first material comprises stainless steel.

19. The method of claim 18, wherein the second material comprises ceramic.

20. The method of claim 17, wherein the second material comprises ceramic.
